(19) United States
(12) Patent Application Publication
(10) Pub. No.: US 2008/0023752 A1
(43) Pub. Date: Jan. 31, 2008

(54) BORON DOPED SiGe HALO FOR NFET TO CONTROL SHORT CHANNEL EFFECT

(75) Inventors: Xiangdong Chen, Poughquag, NY (US); Yung Fu Chong, Singapore (SG); Zhijiong Luo, Carmel, NY (US); Xinlin Wang, Poughkeepsie, NY (US); Haining S. Yang, Wappingers Falls, NY (US)

Correspondence Address: HOFFMAN, WARNICK & D'ALESSANDRO LLC, 75 STATE ST, 14TH FL, ALBANY, NY, 12207, US

(73) Assignees: INTERNATIONAL BUSINESS MACHINES CORPORATION, Armonk, NY (US); CHARTERED SEMICONDUCTOR MANUFACTURING LTD, Singapore (SG)

(21) Appl. No.: 11/460,766

(22) Filed: Jul. 28, 2006

(51) Int. Cl. H01L 29/76; H01L 21/336

(52) U.S. Cl. 257/327; 438/303; 438/305; 438/492; 257/402

(57) ABSTRACT

An n-type field effect transistor (NFET) and methods of forming a halo for an NFET to control the short channel effect are disclosed. One method includes forming a gate over a silicon substrate; recessing the silicon adjacent to the gate; forming a halo by epitaxially growing boron in-situ doped silicon germanium (SiGe) in the recess; and epitaxially growing silicon over the silicon germanium. Alternatively, the halo can be formed by ion implanting boron into an embedded SiGe region within the silicon substrate. The resulting NFET includes a boron doped SiGe halo embedded within the silicon substrate. The embedded SiGe layer may be a relaxed layer without inserting strain in the channel. The high solid solubility of boron in SiGe and low diffusion rate allows formation of a halo that will maintain the sharp profile, which provides better control of the short channel effect and increasing control over NFET threshold voltage roll-off.

### BACKGROUND OF THE INVENTION

1. Technical Field

The invention relates generally to semiconductor device fabrication, and more particularly, to an n-type field effect transistor (NFET) and methods of forming a halo for an NFET to control the short channel effect.

2. Background Art

The continual reduction in the size of metal-oxide semiconductor (MOS) devices has provided significant improvement in circuit density and device performance. As the device channel length of conventional planar MOS field effect transistors (MOSFETs) continues to decrease, the interaction between the source/drain (S/D) and the channel increases, and the S/D begins to gain influence on the channel potential. As a result, transistors with very short channels suffer from problems related to the inability of the gate to adequately control the “on” and “off” states of the channel. For example, these devices typically cannot control threshold voltage roll off. This situation is referred to as the short-channel effect (SCE). There are several methods to suppress SCE, and implementing halo ion implantation is one of the most effective methods. For example, NFETs are oftentimes generated using implanted boron (B) to form a halo. Since most MOSFETs are built on a silicon (Si) substrate, one challenge relative to NFETs is the difficulty in maintaining an adequately sharp halo profile because of the low solid solubility and high diffusivity of boron in silicon.

There is a need in the art for a solution to one or more of the problems of the related art.

### SUMMARY OF THE INVENTION

An n-type field effect transistor (NFET) and methods of forming a halo for an NFET to control the short channel effect (SCE) are disclosed. One method includes forming a gate over a silicon substrate; recessing the silicon adjacent to the gate; forming a halo by epitaxially growing boron in-situ doped silicon germanium (SiGe) in the recess; and epitaxially growing un-doped silicon over the silicon germanium. Alternatively, the halo can be formed by ion implanting boron into an embedded SiGe region within the silicon substrate. The epitaxially grown silicon can be in-situ doped with n-type dopant. The resulting NFET includes a boron doped SiGe halo embedded within the silicon substrate. The embedded SiGe layer may be a relaxed layer without inserting strain in the channel. The high solid solubility of boron in SiGe and low diffusion rate allows formation of a halo that will maintain the sharp profile, which provides better control of the short channel effect and increasing control over NFET threshold voltage roll-off.

A first aspect of the invention provides a method of forming a halo for an n-type field effect transistor (NFET), the method comprising: forming a gate over a silicon substrate; recessing the silicon substrate adjacent to the gate; forming the halo by epitaxially growing boron in-situ doped silicon germanium in the recess; and epitaxially growing silicon over the silicon germanium.

A second aspect of the invention provides a method of forming a halo for an n-type field effect transistor (NFET), the method comprising: forming a gate over a silicon substrate; recessing the silicon substrate adjacent to the gate; first epitaxially growing un-doped silicon germanium in the recess; second epitaxially growing silicon over the silicon germanium; and forming the halo by implanting boron into the silicon germanium.

A third aspect of the invention provides an n-type field effect transistor (NFET) comprising: a gate over a silicon substrate; a halo embedded within the silicon substrate, the halo including boron doped silicon germanium; and a source/drain region.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIGS. 1-6 show embodiments of a method according to the invention.

FIG. 7 shows one embodiment of an NFET according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

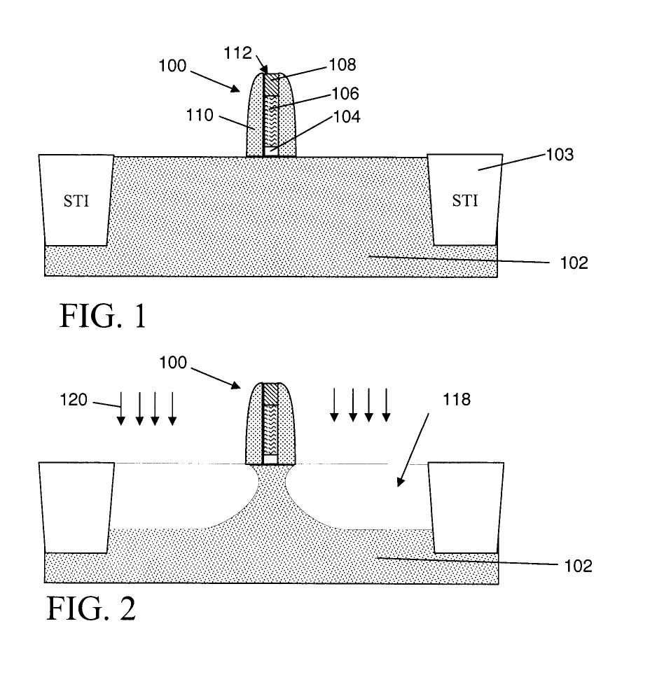

Turning to the drawings, embodiments of a method of forming a halo for an n-type field effect transistor (NFET) will now be described. In FIG. 1, a gate 100 is formed over a silicon substrate 102. Shallow trench isolations (STI) 103 may be formed in silicon substrate 102 in a conventional manner. Silicon substrate 102 may include a bulk silicon (shown) or be provided as a silicon-on-insulator (SOI) substrate. Gate 100 may be formed using any now known or later developed technique such as depositing or growing a gate dielectric 104, depositing polysilicon 106, forming a silicon nitride (Si₃N₄) cap 108, and then forming, patterning and etching (e.g., reaction ion etching (RIE)) to form gate stack 112. A spacer 110 may be formed about gate stack 112 to arrive at gate 100. Although not shown, source/drain extensions may be implanted at this stage. In any event, gate 100 may ultimately have an ultra-short channel length, e.g., well below the 100 nm regime, thus making it susceptible to the problems of the short channel effect (SCE).

Next, as shown in FIG. 2, silicon substrate 102 is recessed adjacent to gate 100 to form a recess 118. In one embodiment, the recessing is provided by performing a reactive ion etch (RIE). However, other recessing techniques, such as wet etching, may also be employed. If a RIE is used, in one embodiment, the RIE may be isotropic. At this stage, any now known or later developed preclean 120 of recess 118 may be performed.

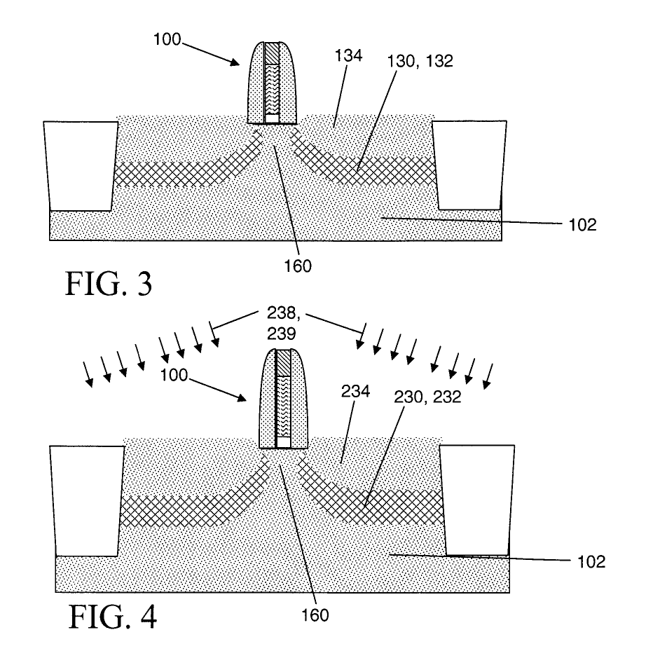

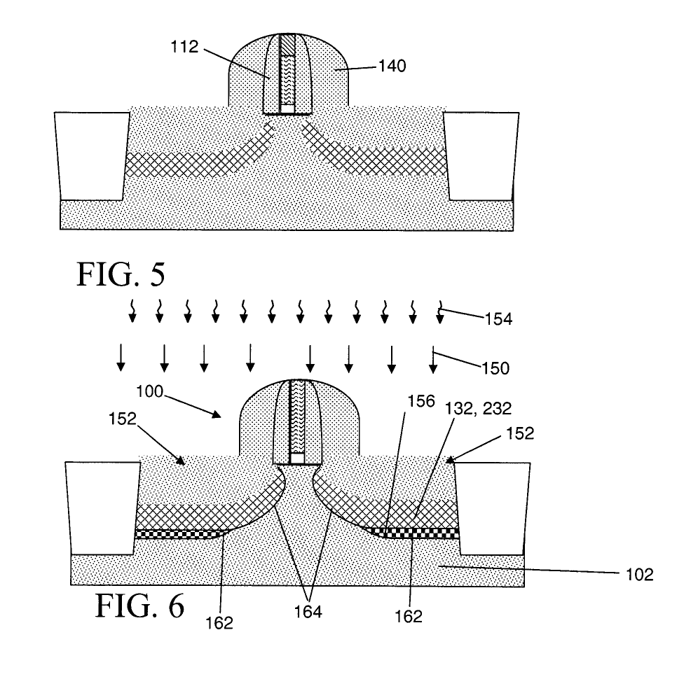

Next, as shown in FIGS. 3 and 4, a halo 130, 230 is formed in silicon substrate 102. This process can be provided in a number of ways. In one embodiment, shown in FIG. 3, a halo 130 is formed by epitaxially growing boron (B) in-situ doped silicon germanium (SiGe) 132 in recess 118 (FIG. 2), followed by epitaxially growing silicon 134 over silicon germanium 132. In an alternative embodiment, shown in FIG. 4, a halo 230 may be formed by epitaxially growing un-doped silicon germanium 232 in recess 118 (FIG. 2), followed by epitaxially growing silicon 234 over silicon germanium 232. Halo 230 may be formed by implanting 238 boron into silicon germanium 232. The halo implant 238 may be conducted either before epitaxially growing silicon 234, or after epitaxially growing silicon 234. In any event, this process results in boron doped silicon germanium halo 130, 230 embedded within silicon substrate 102. In one embodiment, silicon germanium halo 130, 230 is provided as a relaxed layer without inserting strain in a channel 160. The high solid solubility of boron in silicon germanium and low diffusion rate allows formation of a halo 130, 230, which will not lose its profile. Epitaxially grown silicon 134, 234 can be formed in an un-doped stated, or can be in-situ doped with an n-type dopant. Furthermore, an implant 239 may optionally be performed using n-type dopant, such as arsenic (As), antimony (Sb) and/or phosphorous (P), after epitaxially growing un-doped silicon 134, 234 and before forming an outer spacer 140 (FIG. 5).

Next, as shown in FIG. 5, an outer spacer 140 may be formed about (inner) spacer 112, e.g., by depositing silicon nitride (Si₃N₄) or silicon oxide (SiO₂), and etching (e.g., RIE) to form spacer 140. This step may be omitted, if desired. As shown in FIG. 6, an N+dopant such as arsenic (As), antimony (Sb) and/or phosphorous (P) may be implanted 150 to define a source/drain region 152 adjacent to gate 100. At this stage, nitride cap 108 (FIG. 1) may be removed by etching. Next, an anneal 154 may be performed to form source/drain region 152. In one embodiment, an N+ junction 156 of source/drain region 152 may extend lower than a bottom 162 of silicon germanium 132, 232 for the purpose of reducing junction capacitance. Note, however, that N+ junction 156 does not extend beyond a sidewall 164 of silicon germanium 132, 232.

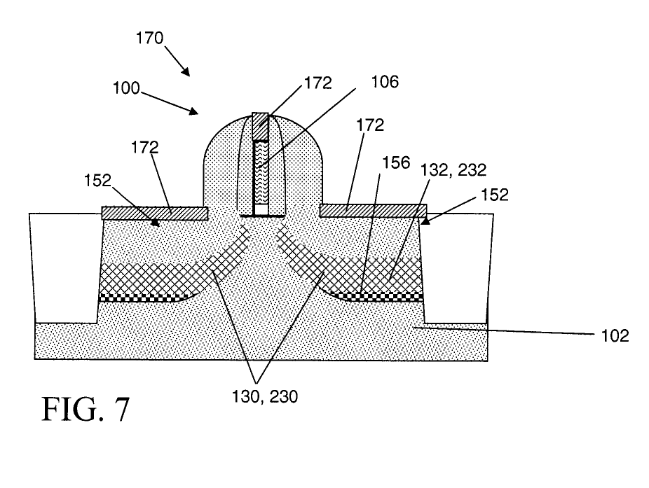

Subsequent standard processing may then be employed to arrive at NFET 170 (FIG. 7). For example, silicide 172 may be formed on source/drain region 152 and polysilicon 106. Contacts (not shown) may be formed. NFET 170 includes, among other things, gate 100 over silicon substrate 102, boron doped silicon germanium halo 130, 230 embedded within silicon substrate 102, and source/drain region 152. As noted above, N+ junction 156 of source/drain region 152 may extend lower than bottom 162 (FIG. 6) of silicon germanium 132, 232, but does not extend beyond sidewall 164 (FIG. 6) of silicon germanium 132, 232. The high solid solubility of boron in SiGe and low diffusion rate allows formation of a highly localized halo 130, 230 that will not lose its profile, which provides better control of the short channel effect and increasing control over NFET 170 threshold voltage roll-off.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method of forming a halo for an n-type field effect transistor (NFET), the method comprising:
forming a gate over a silicon substrate;
recessing the silicon substrate adjacent to the gate;
forming the halo by epitaxially growing boron in-situ doped silicon germanium in the recess; and
epitaxially growing silicon over the silicon germanium.

2. The method of claim 1, further comprising performing a preclean of the recess prior to the forming.

3. The method of claim 1, wherein the silicon is one of: un-doped and in-situ doped with an n-type dopant.

4. The method of claim 3, wherein in the case that the silicon is in-situ doped, further comprising implanting the n-type dopant.

5. The method of claim 1, wherein the recessing includes performing an isotropic reactive ion etch (RIE).

6. The method of claim 1, further comprising:
implanting an N+ dopant to define a source/drain region in the epitaxially grown silicon adjacent to the gate; and
annealing to form the source/drain region.

7. The method of claim 6, wherein an N+ junction of the source/drain region extends lower than a bottom of the silicon germanium.

8. The method of claim 6, wherein the N+ dopant is selected from the group consisting of: arsenic (As), antimony (Sb) and phosphorus (P).

9. The method of claim 6, wherein the gate includes a first spacer, and further comprising forming a second spacer about the first spacer prior to the implanting.

10. A method of forming a halo for an n-type field effect transistor (NFET), the method comprising:
forming a gate over a silicon substrate;
recessing the silicon substrate adjacent to the gate;
first epitaxially growing un-doped silicon germanium in the recess;
second epitaxially growing silicon over the silicon germanium; and
forming the halo by implanting boron into the silicon germanium.

11. The method of claim 10, further comprising performing a preclean of the recess prior to the first epitaxially growing.

12. The method of claim 10, wherein the epitaxially grown silicon is one of: un-doped and in-situ doped with an n-type dopant.

13. The method of claim 12, wherein in the case that the epitaxially grown silicon is in-situ doped, further comprising implanting the n-type dopant.

14. The method of claim 10, wherein the recessing includes performing a reactive ion etch (RIE).

15. The method of claim 10, further comprising:
implanting an N+ dopant to define a source/drain region in the silicon adjacent to the gate; and
annealing to form the source/drain region.

16. The method of claim 15, wherein an N+ junction of the source/drain region extends lower than a bottom of the silicon germanium.

17. The method of claim 15, wherein the halo forming occurs prior to the second epitaxial growing.

18. The method of claim 15, wherein the gate includes a first spacer, and further comprising forming a second spacer about the first spacer prior to the implanting.

19. An n-type field effect transistor (NFET) comprising:
a gate over a silicon substrate;
a halo embedded within the silicon substrate, the halo including a boron doped silicon germanium; and
a source/drain region.

20. The NFET of claim 19, wherein an N+ junction of the source/drain region extends lower than a bottom of the halo.
